(19) United States
(12) Patent Application Publication
(10) Pub. No.: US 2010/0032823 A1
(43) Pub. Date: Feb. 11, 2010

(54) SEMICONDUCTOR DEVICE AND METHOD OF FABRICATING THE SAME

(75) Inventor: Takahiro Ide, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/534,521

(22) Filed: Aug. 3, 2009

(30) Foreign Application Priority Data
Aug. 5, 2008 (JP) 2008-202292

(51) Int. Cl. H01L 23/48; H01L 21/56; H01L 23/29

(52) U.S. Cl. 257/690; 438/124; 257/E23.01; 257/E23.119; 257/E21.502

(57) ABSTRACT

A semiconductor device includes: a semiconductor substrate having an active area formed on a major surface of the semiconductor substrate; an interlayer insulating film and a wiring layer formed on predetermined regions of the active area; and a sealing resin film covering the interlayer insulating film, the wiring layer, and the major surface of the semiconductor substrate and filling a groove surrounding the active area. The sealing resin film 9 and a junction made of the sealing resin film filled in the groove are formed to be continuous with each other. Thus, the occurrence of a separation of the sealing resin and the inward propagation thereof are prevented.

### CROSS REFERENCE TO RELATED APPLICATION

This application is based upon and claims the benefit of priority from Japanese Patent Application No. 2008-202292, filed on Aug. 5, 2008, the entire contents of which are incorporated herein by reference.

### BACKGROUND

In recent years, with the rapid spread of small electronic gadgets such as mobile phones, a need has arisen for thin, compact, and light semiconductor devices. In response to this need, many reports have been made on wafer level chip size package (hereinafter abbreviated to WCSP) structures in which packaging is performed in wafer form.

In some WCSPs, underfilling is performed after the mounting of a semiconductor chip on a mount board in order to increase life in terms of packaging reliability and improve mechanical strength in a fall, the bending of a substrate, and the like. In the case where underfilling is performed, the applied amount of an underfill material depends on the ejected amount thereof from a dispense nozzle and permeability based on capillary action. This makes it difficult to apply the underfill material uniformly over the entire surface of the semiconductor chip.

Accordingly, non-uniform or poor wettability may occur at side surfaces of the semiconductor chip due to the non-uniform application of the underfill material, a shortage of the applied amount thereof, or the like. When such non-uniform or poor wettability occurs, a separation may occur at a side surface of the package because stress is concentrated at the silicon substrate, sealing resin coating the surface of an element, or the interface therebetween. This may cause the following problem: the separation at the side surface of the package propagates inward, and causes breakages of the active area and the wiring layer.

Some semiconductor chips have chip rings or grooves in order to prevent damage during dicing or the entry of impurities contained in incoming water into the active area and the wiring layer (e.g., see Japanese Patent Application Publication No. 2007-329396). However, in many cases, a separation caused by the above-described causes occurs in such a manner that delamination is caused at the interfaces between the silicon substrate and each of the active area and the wiring layer, and propagates inward. Accordingly, the propagation thereof cannot be prevented by chip rings or conventional technologies.

### SUMMARY

Aspects of the invention relate to a semiconductor device and a method of fabricating the same, and particularly to a semiconductor device package structure and a method of fabricating the same.

In one aspect of the invention, a semiconductor device e may include a semiconductor substrate having an active area formed on a major surface of the semiconductor substrate; an interlayer insulating film and a wiring layer formed on predetermined regions of the active area; and a sealing resin film covering the interlayer insulating film, the wiring layer, and the major surface of the semiconductor substrate, and filling a groove located outside the active area.

In another aspect of the invention, a method of fabricating a semiconductor device may include forming an active area on a major surface of a semiconductor substrate; forming a groove in the semiconductor substrate, the groove surrounding the active area; forming an interlayer insulating film and a wiring layer in predetermined regions on the active area; and forming a sealing resin film that covers the interlayer insulating film, the wiring layer, and the major surface of the semiconductor substrate and fills the groove.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross-sectional view schematically showing a semiconductor device according to a first embodiment of the present invention.

FIG. 2 is a cross-sectional view schematically showing the semiconductor device according to the first embodiment of the present invention.

FIG. 3 is a cross-sectional view schematically showing the semiconductor device according to the first embodiment of the present invention.

FIGS. 4A to 4C are cross-sectional views schematically showing some of the steps in a method of fabricating the semiconductor device according to the first embodiment of the present invention.

FIGS. 5A to 5C are cross-sectional views schematically showing some of the steps in the method of fabricating the semiconductor device according to the first embodiment of the present invention.

FIGS. 6A to 6C are cross-sectional views schematically showing some of the steps in the method of fabricating the semiconductor device according to the first embodiment of the present invention.

FIGS. 7A and 7B are cross-sectional views schematically showing some of the steps in the method of fabricating the semiconductor device according to the first embodiment of the present invention.

FIG. 8 is a cross-sectional view schematically showing a semiconductor device according to a second embodiment of the present invention.

FIG. 9 is a cross-sectional view schematically showing the semiconductor device according to the second embodiment of the present invention.

FIGS. 10A and 10B are cross-sectional views schematically showing some of the steps in a method of fabricating the semiconductor device according to the second embodiment of the present invention.

FIG. 11 is a cross-sectional view showing a semiconductor device according to one aspect of an embodiment of the present invention, wherein the semiconductor device is mounted on a mount board with underfill interposed therebetween.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

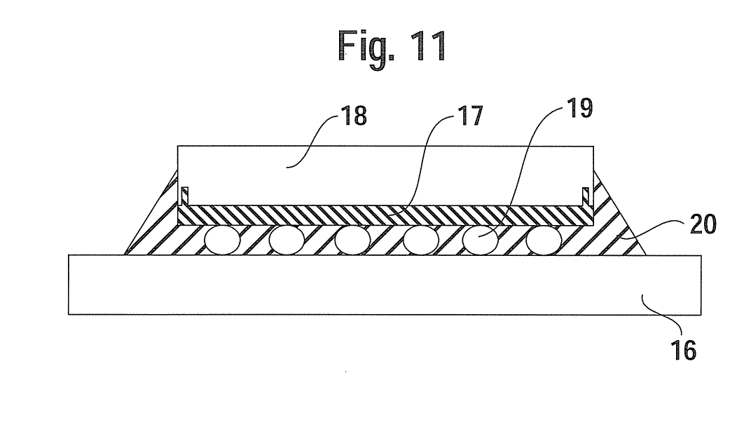

First, FIG. 11 is a cross-sectional view showing a semiconductor device according to one aspect of an embodiment of the present invention. In this drawing, the semiconductor device is mounted on a mount board with underfill interposed therebetween.

A mount board 16 and a silicon substrate 18, which has a major surface thereof covered with sealing resin 17, are connected to each other through external terminals 19. Underfill 20 is applied to the connection therebetween and side surfaces of the semiconductor substrate. The unevenness, shortage, or the like of this underfill 20 may stress the side surfaces of the semiconductor chip.

In this embodiment, the sealing resin 17 fills a groove which is formed to surround an active area (not shown) formed in the major surface of the silicon substrate 18. The filling of the groove with the sealing resin can prevent a separation at a side surface of the package and the inward propagation thereof, which cannot be prevented with conventional structures.

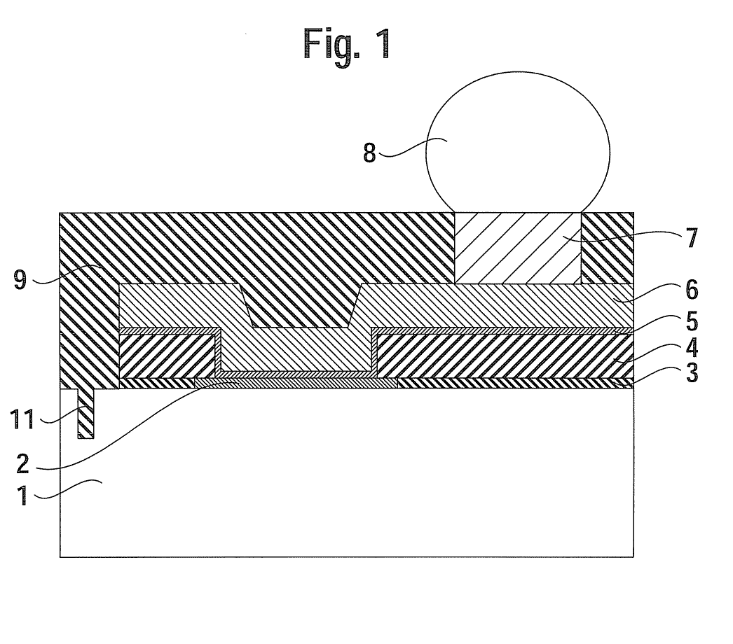

FIG. 1 is a cross-sectional view schematically showing a semiconductor device according to a first embodiment of the present invention. The semiconductor device according to the first embodiment of the present invention will be described with reference to FIG. 1.

In practice, external terminals connected to a mount board are formed to be vertically and laterally aligned with each other on the semiconductor chip. However, this embodiment will be described with attention focused on part of the semiconductor chip, particularly the vicinity of an end face of the semiconductor chip.

In the semiconductor device according to the first embodiment of the present invention, an electrode pad 2 for electrically connecting the semiconductor chip and an external component is provided on a silicon substrate 1 having an active area, a wiring layer, and the like formed on its major surface.

In regions except the region in which the electrode pad 2 is provided, for example, an insulating layer 3 made of a silicon oxide film or the like is formed as a passivation film.

On the electrode pad 2 and the insulating layer 3, a resin layer 4 is formed which has an opening partially on the electrode pad 2. The resin layer 4 is made of, for example, polyimide or the like, and has functions such as ensuring the surface insulation of the semiconductor chip and reducing mechanical stress in the semiconductor chip. On the resin layer 4 and the side and bottom surfaces of the opening, an under barrier metal (UBM) layer 5 is provided.

On the UBM layer 5, a redistribution layer 6 made of, for example, aluminum or copper is formed. On a portion of the redistribution layer 6, a post 7 made of a metal column is provided. On the post 7, an external terminal 8 made of a solder ball is formed to be electrically connected to the redistribution layer 6.

On the redistribution layer 6, sealing resin 9 is formed to cover the redistribution layer 6 and the major surface of the silicon substrate 1. The sealing resin 9 is made of, for example, epoxy-based resin or the like. The post 7 is buried in the sealing resin 9.

The external terminal 8 may partially be buried in the sealing resin 9. It should be noted that in the present invention, the term “sealing resin” refers to resin in an outermost layer which is provided to cover the redistribution layer 6 and the major surface of the silicon substrate 1.

On the major surface of the silicon substrate 1, a groove 10 in which a junction 11 is to be formed is provided in a region outward of the active area. The inside of the groove 10 is filled with sealing resin. The sealing resin 9 and the sealing resin filling the groove 10 are formed to be continuous with each other.

It is desired that the groove width of the groove 10 be greater than the grain size of a filler contained in the sealing resin 9 because the filling properties of the sealing resin 9 into the groove 10 are improved. Specifically, it is desired that the groove 10 have a width of 10 μm or more which is as wide as possible.

In the case where no elements are formed outward of a region in which the electrode pads 2 are formed, the groove 10 is formed in a region outward of the electrode pads, and may be formed in a region in which a conventional chip ring would be formed. In other words, the groove 10 is formed outward of a region in which the redistribution layer 6 is formed.

It should be noted that the groove 10 is continuously provided in the silicon substrate 1 but may be formed as separate segments in regions outward of the active area of the semiconductor chip.

However, the groove 10 continuously formed to surround the active area can more effectively prevent a separation of the sealing resin 9 and the inward propagation thereof.

The groove 10 preferably has such a depth that the groove 10 penetrates a multilayer wiring structure and reaches the inside of the silicon substrate 1. Making the groove reach the inside of the silicon substrate 1 can more effectively prevent a separation of the sealing resin 9 and the inward propagation thereof.

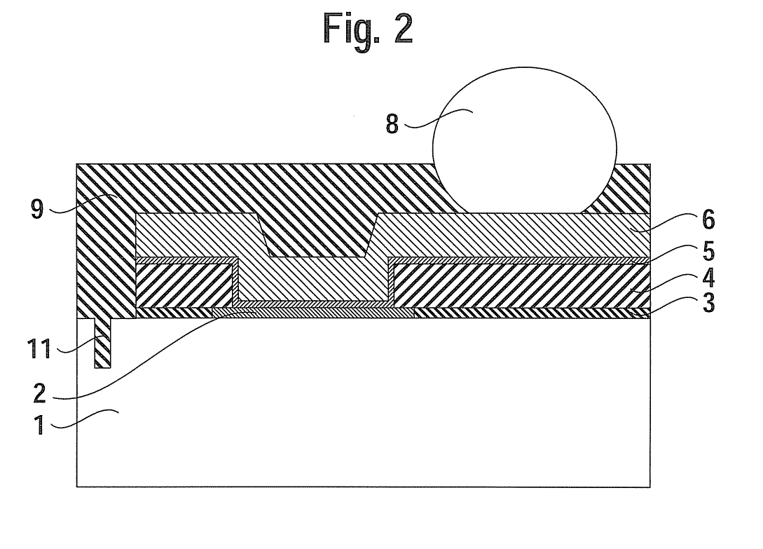

Other than the post-type structure shown in FIG. 1, it is possible to employ a redistribution-type structure in which the external terminal 8 is connected directly to the redistribution layer 6 as shown in FIG. 2. In the case of the redistribution-type structure, possible materials for the sealing resin 9 include, for example, benzo cyclo butane (BCB)-based resins, poly benzo-oxazole (PBO)-based resins, phenol-based resins, polyimide-based resins, epoxy-based resins, and the like.

The above-described materials include, for example, a resin such as polyimide which is used as the resin layer 4 provided to ensure the surface insulation of the semiconductor chip and reduce mechanical stress in the semiconductor chip.

However, in this embodiment, such resin is used as the sealing resin 9 formed in the outermost layer, and the sealing resin 9 is filled in the groove 10 to provide the junction 11. This can prevent a separation of the sealing resin 9 and the inward propagation thereof.

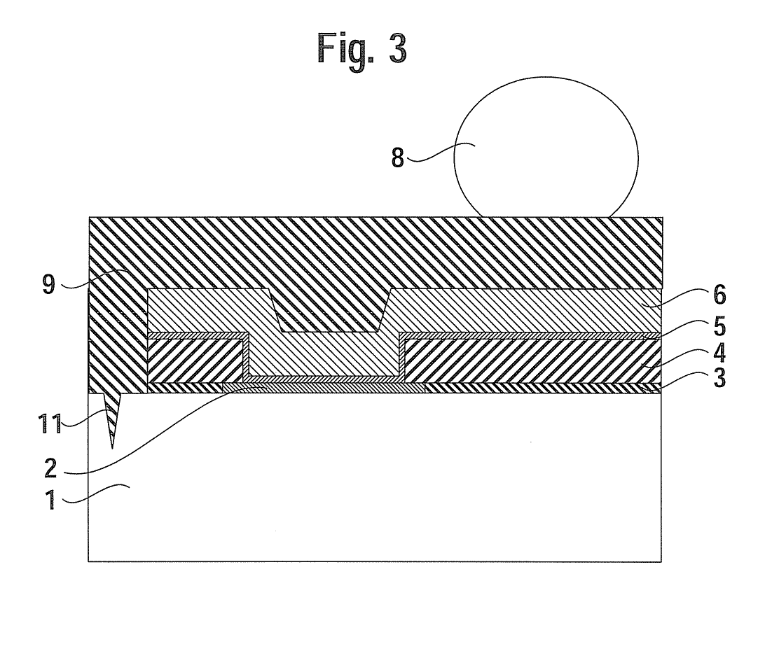

The shape of the junction 11 may be, as shown in FIG. 3, a tapered shape which is formed when the groove 10 is formed by etching. As long as the sealing resin 9 fills the groove 10, an anchor effect can be obtained. This can prevent the occurrence of a separation of the sealing resin 9.

In this embodiment, since the junction 11 integrated with the sealing resin 9 is formed in the groove 10, the occurrence of a separation at a side surface of the package and the inward propagation thereof can be prevented. Specifically, since the sealing resin 9 is buried in the groove 10, the occurrence of a separation can be prevented by an anchor effect.

Further, even in the case where delamination occurs at the interface between the silicon substrate 1 and the sealing resin 9, the inward propagation of a separation can be stopped by making the junction 11 reach the inside of the silicon substrate 1.

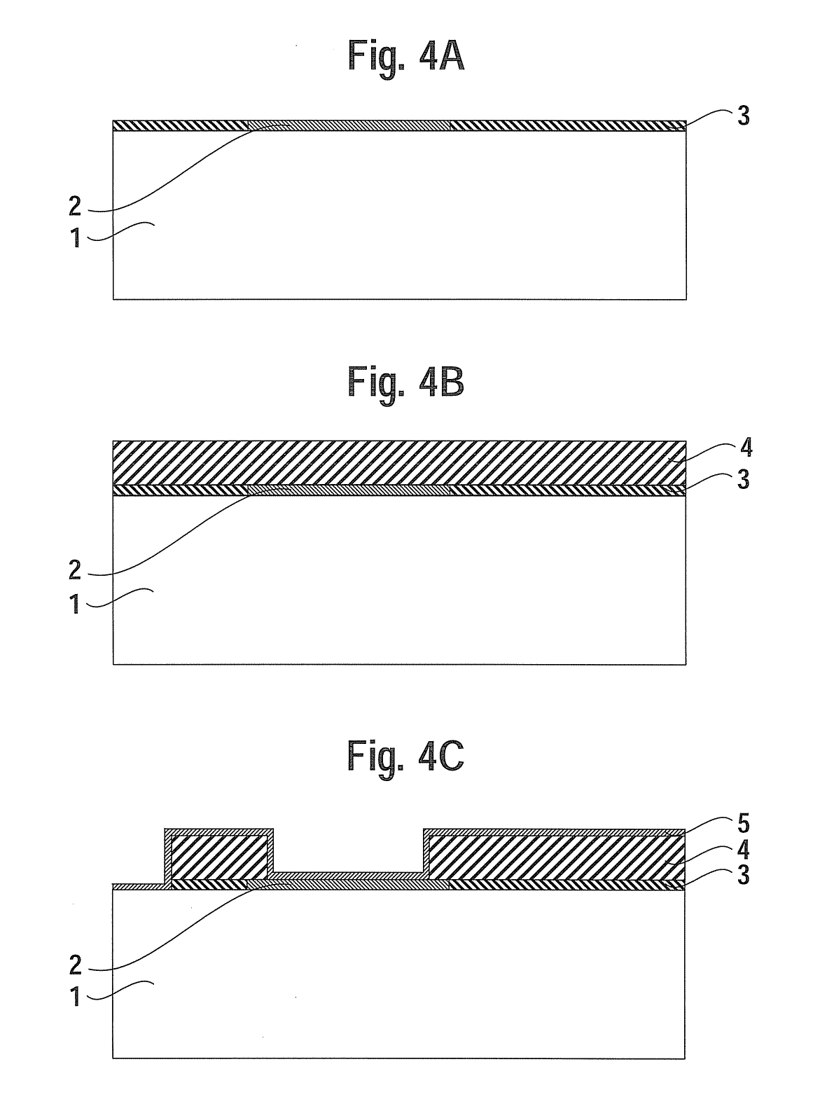

Next, a method of fabricating the semiconductor device according to the first embodiment of the present invention will be described. FIGS. 4A to 4C are cross-sectional views showing steps in the fabrication of the semiconductor device according to the first embodiment of the present invention.

First, as shown in FIG. 4A, the electrode pad 2 for electrically connecting the semiconductor chip and an external component and the insulating layer 3 are formed in predetermined regions on the silicon substrate 1 having an active area, a wiring layer, and the like (not shown) formed on its major surface.

Next, as shown in FIG. 4B, the resin layer 4 is formed on the electrode pad 2 and the insulating layer 3. Then, as shown in FIG. 4C, in the resin layer 4, openings are formed in a region on the electrode pad 2, a region where a groove is to be formed, and a dicing line region (not shown).

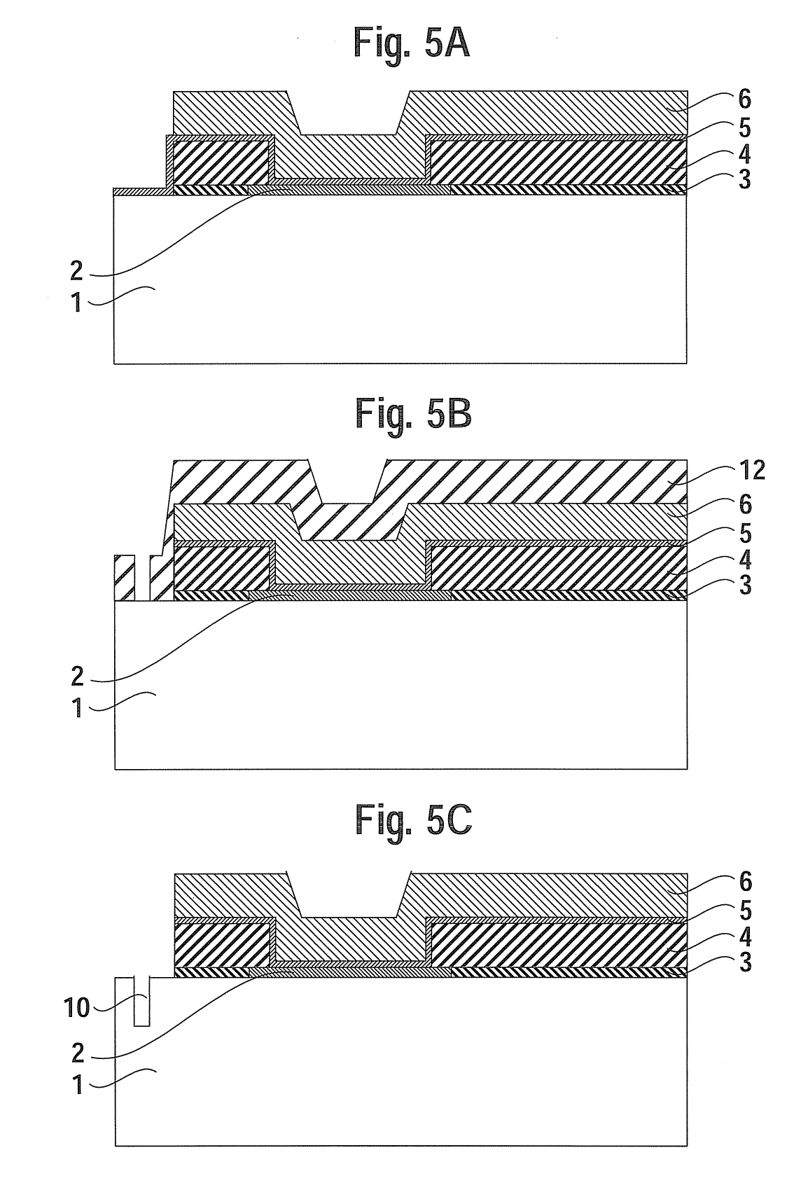

Thereafter, the UBM layer 5 is formed on the silicon substrate 1, the resin layer 4, and the electrode pad 2. After the formation of the UBM layer 5, as shown in FIG. 5A, the redistribution layer 6 is formed on the UBM layer 5. Using the redistribution layer 6 as a mask, the UBM layer 5 is selectively removed. At this time, the UBM layer 5 in the dicing line region (not shown) is also removed.

Subsequently, as shown in FIG. 5B, a hard mask 12 is formed which has an opening only in a region where a groove is to be formed. Then, as shown in FIG. 5C, the groove 10 is formed by dry etching such as reactive ion etching (RIE) using a gas such as CF₄ or CHF₃. After the formation of the groove 10, the hard mask 12 is removed.

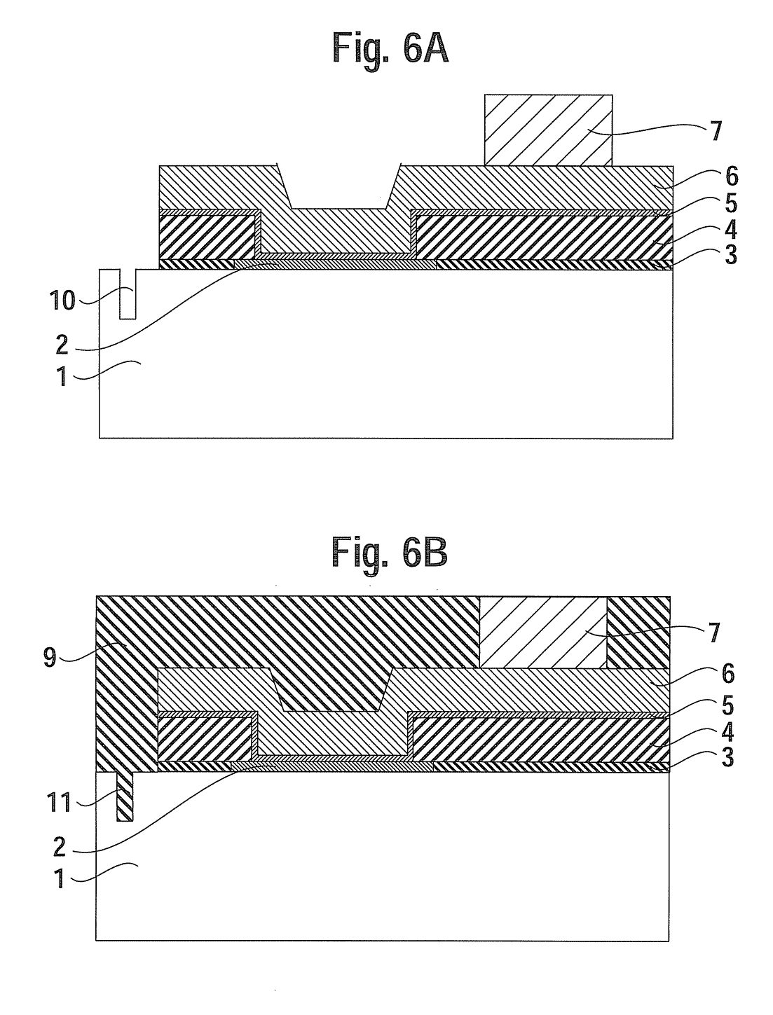

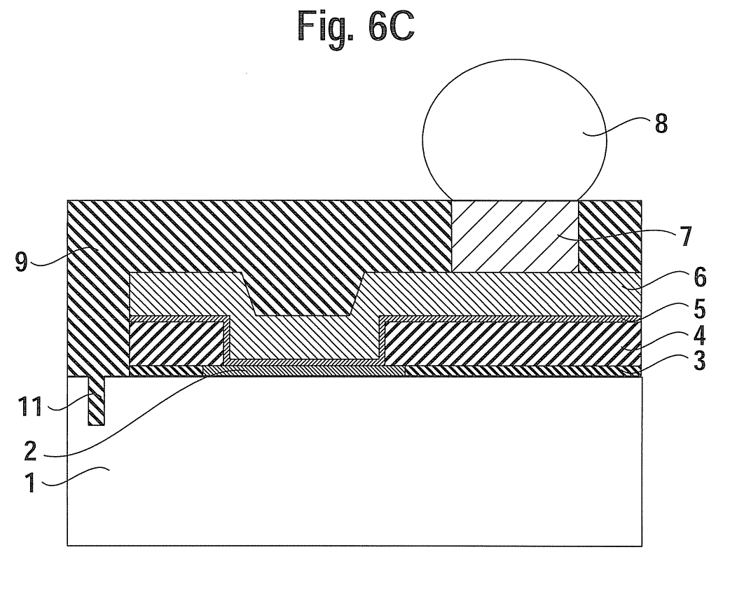

In the case of a post-type semiconductor package structure, as shown in FIG. 6A, the post 7 is formed in a predetermined region on the redistribution layer 6. Then, as shown in FIG. 6B, the redistribution layer 6, the post 7, and the major surface of the silicon substrate 1 are covered with the sealing resin 9. At the same time, the resin is filled in the groove 10 to form the junction 11.

In the case of the post type, examples of possible methods of forming the sealing resin 9 include: a method in which liquid resin is applied by printing and then hardened by curing; and a method in which resin tablets are molded by transfer-molding or the like.

After the formation of the sealing resin 9, as shown in FIG. 6C, the post 7 is exposed, and the external terminal 8 made of solder is attached to the top of the post 7 by ball attachment, solder printing, or the like, and then fused by reflow to be formed.

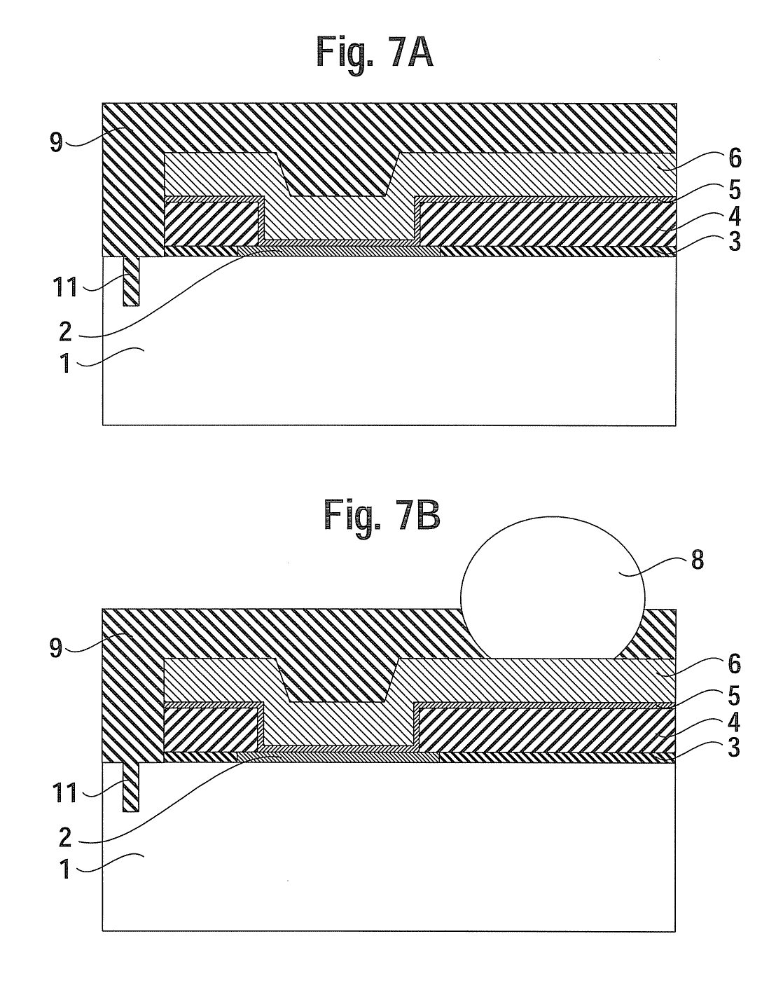

On the other hand, in the case of a redistribution-type semiconductor package structure, as shown in FIG. 7A, the redistribution layer 6 and the major surface of the silicon substrate 1 are covered with the sealing resin 9. At the same time, the resin is filled in the groove 10 to form the junction 11.

In the case of the redistribution type, examples of possible methods of forming the sealing resin 9 include: a method in which the sealing resin 9 is formed by spin coating, printing, using a dispenser, or the like using liquid resin; and a method in which resin tablets are molded by transfer-molding or the like.

After the formation of the sealing resin 9, as shown in FIG. 7B, an opening through which the redistribution layer 6 is exposed is selectively formed in the sealing resin 9. Then, the external terminal 8 made of solder is attached to this opening by ball attachment, solder printing, or the like and then fused by reflow to be formed.

According to this embodiment, the following effects can be obtained. That is, since the junction 11 integrated with the sealing resin 9 is formed in the groove 10, the occurrence of a separation at a side surface of the package can be prevented.

Specifically, since the sealing resin 9 is buried in the groove 10, the occurrence of a separation at a side surface of the package can be prevented by an anchor effect. Further, even in the case where delamination occurs at the interface between the silicon substrate 1 and the sealing resin 9, the inward propagation of a separation can be stopped by making the junction 11 reach the inside of the silicon substrate 1.

It should be noted that the position of the step of forming the groove 10 in the sequence is not limited to that described in this embodiment, but may be a desired position in the sequence before the step of forming the sealing resin 9.

For example, after the electrode pad 2 and the insulating layer 3 are formed in the step of FIG. 4A, the hard mask 12 may be formed, followed by the formation of the groove 10.

### Second Embodiment

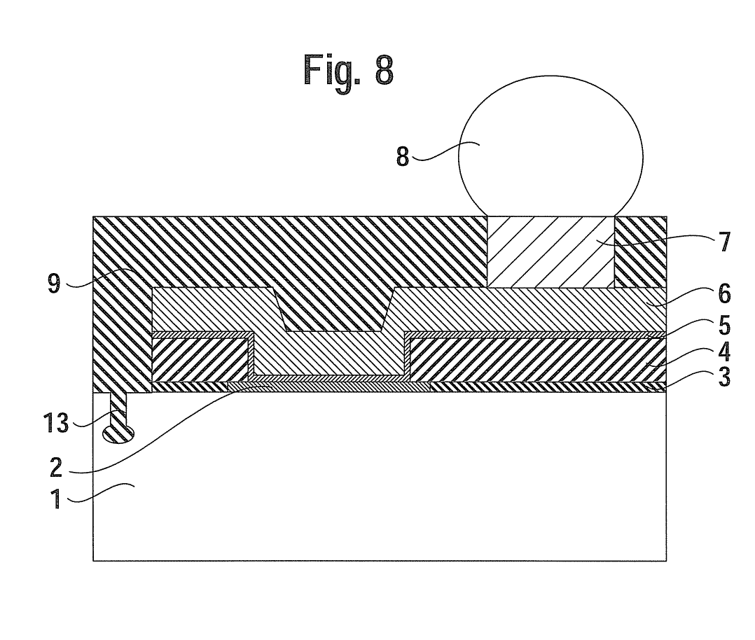

FIG. 8 is a cross-sectional view schematically showing a semiconductor device according to a second embodiment of the present invention. The semiconductor device according to the second embodiment of the present invention will be described with reference to FIG. 8. It should be noted that in FIG. 8, the same components as those of the first embodiment are denoted by the same reference numerals.

Compared to the first embodiment, the second embodiment has a feature where a groove has a region with a width greater than the groove width of the groove.

Specifically, as shown in FIG. 8, the second embodiment has a feature where the inside shape of a groove 14 is enlarged to provide a junction 13 having a region with a width greater than the groove width of the groove 14. However, similar to the first embodiment, the sealing resin 9 and sealing resin filling the groove 14 are formed to be continuous with each other.

With the region having a width greater than the groove width of the groove 14, the binding between the silicon substrate 1 and the sealing resin 9 can be made firmer than that of the first embodiment. Thus, a higher anchor effect can be obtained.

The groove 14 preferably has such a depth that the groove 14 penetrates a multilayer wiring structure and reaches the inside of the silicon substrate 1. Making the groove reach the inside of the silicon substrate 1 can more effectively prevent a separation of the sealing resin 9 and the inward propagation thereof.

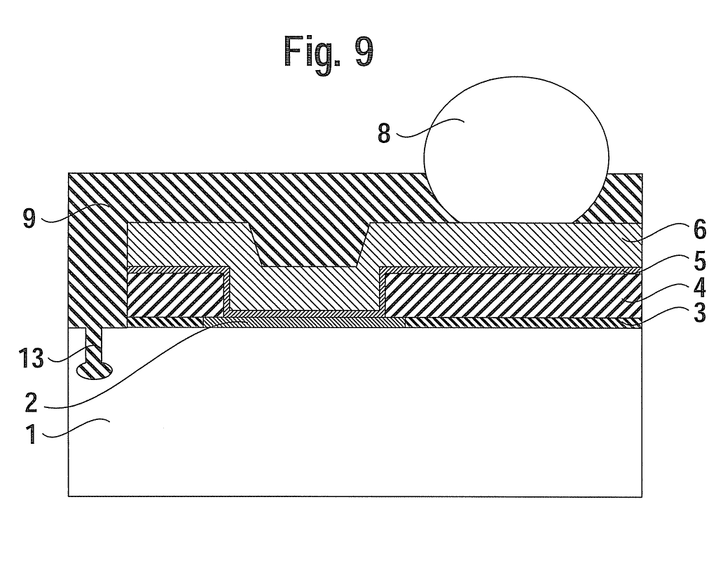

Other than the post-type structure shown in FIG. 8, it is possible to employ a redistribution-type structure in which the external terminal 8 is connected directly to the redistribution layer 6 as shown in FIG. 9. Also in the case of the redistribution-type structure, the binding between the silicon substrate 1 and the sealing resin 9 can be made firmer than that of the first embodiment. Thus, a higher anchor effect can be obtained.

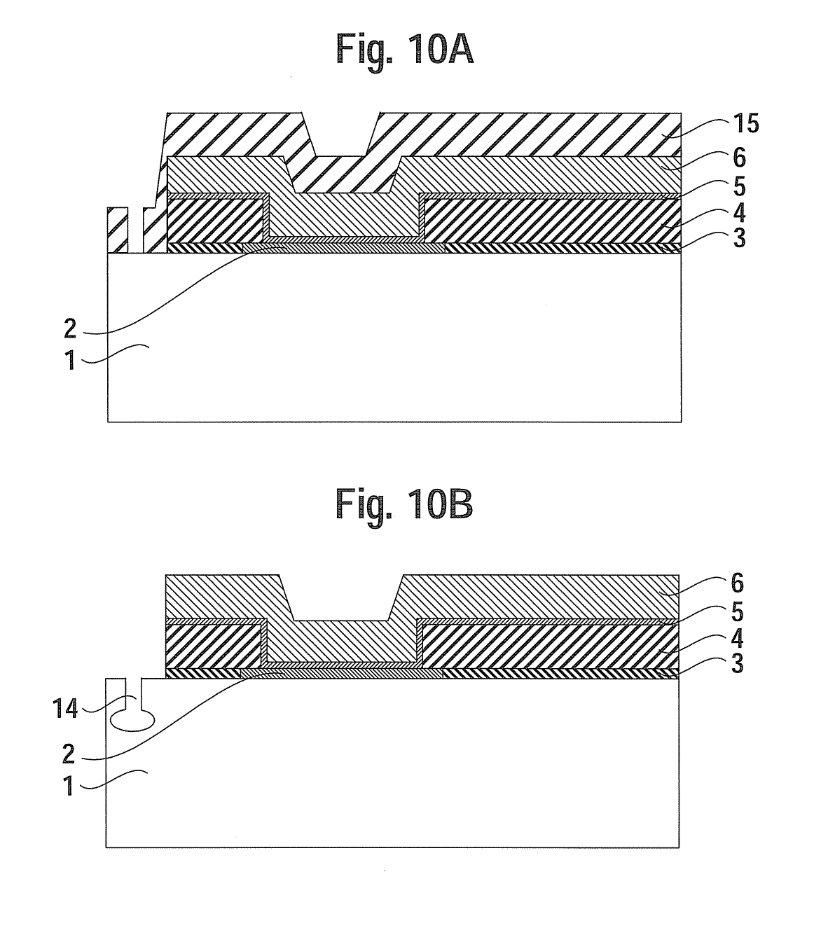

Next, a method of fabricating the semiconductor device according to the second embodiment of the present invention will be described. FIGS. 10A and 10B are cross-sectional views showing steps in the fabrication of the semiconductor device according to the second embodiment of the present invention.

Steps until the redistribution layer 6 is formed are the same as the aforementioned ones of the first embodiment and therefore will not be described here. First, as shown in FIG. 10A, a hard mask 15 is formed which has an opening only in a region where the groove 14 is to be formed.

Then, the groove 14 is formed by dry etching such as reactive ion etching (RIE) using a gas such as CF₄ or CHF₃. By performing wet etching following the dry etching, a region having a width greater than the groove width of the groove 14 can be formed in the groove 14 as shown in FIG. 10B. The subsequent steps are similar to those of the first embodiment and therefore will not be described here.

Similar to the first embodiment, in the case of the post type, examples of possible methods of forming the sealing resin 9 include: a method in which liquid resin is applied by printing and then hardened by curing; and a method in which resin tablets are molded by transfer-molding or the like.

On the other hand, in the case of the redistribution type, examples of possible methods of forming the sealing resin 9 include: a method in which the sealing resin 9 is formed by spin coating, printing, using a dispenser, or the like using liquid resin; and a method in which resin tablets are molded by transfer-molding or the like.

It should be noted that the position of the step of forming the groove 14 in the sequence is not limited to that described in this embodiment, but may be a desired position in the sequence before the step of forming the sealing resin 9. For example, after the electrode pad 2 and the insulating layer 3 are formed, the hard mask 15 may be formed, followed by the formation of the groove 14.

According to this embodiment, the following effects can be obtained. That is, since the junction 13 integrated with the sealing resin 9 is formed in the groove 14, the occurrence of a separation at a side surface of the package can be prevented.

Moreover, since the region having a width greater than the groove width of the junction 13 is provided in the junction 13, the binding between the silicon substrate 1 and the sealing resin 9 can be made firmer, and thus a higher anchor effect can be obtained.

Further, even in the case where delamination occurs at the interface between the silicon substrate 1 and the sealing resin 9, the inward propagation of a separation can be stopped by making the junction 13 reach the inside of the silicon substrate 1.

It should be noted that the present invention is not limited to the above-described embodiments, but various modifications can be made thereto without departing from the spirit of the present invention. For example, in the second embodiment, part of the groove 14 may be in a tapered shape formed when the groove 14 is formed by etching.

What is claimed is:

1. A semiconductor device, comprising:
a semiconductor substrate having an active area formed on a major surface of the semiconductor substrate;
an interlayer insulating film and a wiring layer formed on predetermined regions of the active area; and
a sealing resin film covering the interlayer insulating film, the wiring layer, and the major surface of the semiconductor substrate, and filling a groove located outside the active area.

2. The semiconductor device according to claim 1, wherein the groove surrounds the active area.

3. The semiconductor device according to claim 1, wherein a groove width of the groove is 10 μm or more.

4. The semiconductor device according to claim 1, wherein the groove has a region formed therein, the region having a width greater than a groove width of the groove.

5. The semiconductor device according to claim 1, wherein the sealing resin film filling the groove reaches the inside of the semiconductor substrate.

6. The semiconductor device according to claim 1, wherein the sealing resin film includes one selected from the group consisting of benzo cyclo butane (BCB)-based resins, poly benzo-oxazole (PBO)-based resins, phenol-based resins, polyimide-based resins, epoxy-based resins.

7. The semiconductor device according to claim 1, further comprising:
an electrode pad for electrically connecting the semiconductor chip and an external component located in predetermined region on the active area, wherein the groove located outside the electrode pad.

8. A method of fabricating a semiconductor device, comprising:
forming an active area on a major surface of a semiconductor substrate;
forming a groove in the semiconductor substrate, the groove surrounding the active area;
forming an interlayer insulating film and a wiring layer in predetermined regions on the active area; and
forming a sealing resin film that covers the interlayer insulating film, the wiring layer, and the major surface of the semiconductor substrate and fills the groove.

9. The method according to claim 8, wherein the groove formed by dry etching.

10. The method according to claim 8, wherein a groove width of the groove is 10 μm or more.

11. The method according to claim 8, wherein the sealing resin film filling the groove reaches the inside of the semiconductor substrate.

12. The method according to claim 8, wherein the groove has a region formed therein, the region having a width greater than a groove width of the groove.

13. The method according to claim 12, wherein the groove formed by wet etching following the dry etching.

14. The method according to claim 8, wherein the sealing resin film formed by printing liquid resin and hardened the liquid resin by curing.

15. The method according to claim 8, wherein the sealing resin film formed by transfer-molding applied resin tablets.
